(19) United States
(12) Patent Application Publication
(10) Pub. No.: US 2024/0094460 A1
(43) Pub. Date: Mar. 21, 2024

(54) OPTOELECTRONIC PACKAGE

(71) Applicant: Advanced Semiconductor Engineering, Inc., Kaohsiung (TW)

(72) Inventors: Jr-Wei LIN, Kaohsiung (TW); Mei-Ju LU, Kaohsiung (TW)

(73) Assignee: Advanced Semiconductor Engineering, Inc., Kaohsiung (TW)

(21) Appl. No.: 17/949,143

(22) Filed: Sep. 20, 2022

(51) Int. Cl. G02B 6/12; G02B 6/122; G02B 6/30

(52) U.S. Cl. CPC G02B 6/12004; G02B 6/1228; G02B 6/305

(57) ABSTRACT

An optoelectronic package is provided. The optoelectronic package includes a photonic component, a connection structure, and an electronic component. The photonic component has an active surface. The connection structure is in contact with the active surface of the photonic component. The electronic component is embedded in the connection structure. The connection structure includes a first redistribution structure in contact with the active surface of the photonic component.

### BACKGROUND

### 1. Field of the Disclosure

The present disclosure relates to an optoelectronic package, and particularly to an optoelectronic package including a redistribution structure formed on a photonic component.

### 2. Description of the Related Art

A silicon-photonics device has advantages of high speed transmission and low power consumption, and thus can be applied, for example, in the field of communication. A silicon-photonics device may include a photonic integrated circuit (PIC), electronic integrated circuit (EIC), fiber, and other optical/electronic components. With the rapid growth of the electronics industry, ever smaller PICs and EICs are required, and the issue of warpage in manufacturing processes is becoming much more important.

### SUMMARY

In some embodiments, an optoelectronic package includes a photonic component, a connection structure, and an electronic component. The photonic component has an active surface. The connection structure is in contact with the active surface of the photonic component. The electronic component is embedded in the connection structure. The connection structure includes a first redistribution structure in contact with the active surface of the photonic component.

In some embodiments, an optoelectronic package includes a photonic component, an electronic component and an encapsulant. The photonic component has a recess region on an active surface of the photonic component. The photonic component has a waveguide. The waveguide is exposed from the recess region of the photonic component. The electronic component is disposed over the active surface of the photonic component. The encapsulant encapsulates the electronic component. A lateral surface of the encapsulant is noncoplanar with a lateral surface of the recess region of the photonic component.

In some embodiments, an optoelectronic package includes an electronic component, a first redistribution structure, a second redistribution structure, and a photonic component. The electronic component has a first surface. The first redistribution structure is disposed over the first surface of the electronic component. The photonic component is disposed over the first redistribution structure. A via of the first redistribution structure is tapered toward the photonic component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an optoelectronic package according to some embodiments of the present disclosure.

FIG. 2 illustrates a cross-sectional view of an optoelectronic package according to some embodiments of the present disclosure.

FIG. 3 illustrates a cross-sectional view of an optoelectronic package according to some embodiments of the present disclosure.

FIG. 4 illustrates a cross-sectional view of an optoelectronic package according to some embodiments of the present disclosure.

FIG. 5 illustrates a cross-sectional view of an optoelectronic package according to some embodiments of the present disclosure.

FIG. 6 illustrates a cross-sectional view of an optoelectronic package according to some embodiments of the present disclosure.

FIG. 7 illustrates a cross-sectional view of an optoelectronic package according to some embodiments of the present disclosure.

FIG. 8 illustrates a cross-sectional view of an optoelectronic package according to some embodiments of the present disclosure.

FIG. 9 illustrates a cross-sectional view of an optoelectronic package according to some embodiments of the present disclosure.

FIG. 10 illustrates a cross-sectional view of an optoelectronic package according to some embodiments of the present disclosure.

FIG. 11 illustrates a cross-sectional view of an optoelectronic package according to some embodiments of the present disclosure.

FIG. 12A, FIG. 12B, FIG. 12C, FIG. 12D, FIG. 12E, FIG. 12F, FIG. 12G, FIG. 12H, FIG. 12I, FIG. 12J and FIG. 12K illustrate various stages of an example of a method for manufacturing an optoelectronic package according to some embodiments of the present disclosure.

FIG. 13A and FIG. 13B illustrate various stages of an example of a method for manufacturing an optoelectronic package according to some embodiments of the present disclosure.

FIG. 14 illustrates a cross-sectional view of a comparative optoelectronic package.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein the term “active surface” may refer to a surface of an electronic component or passive element on which contact terminals such as contact pads are disposed. The term “active surface” may also refer to a surface from which an optical component transmits or receives signals.

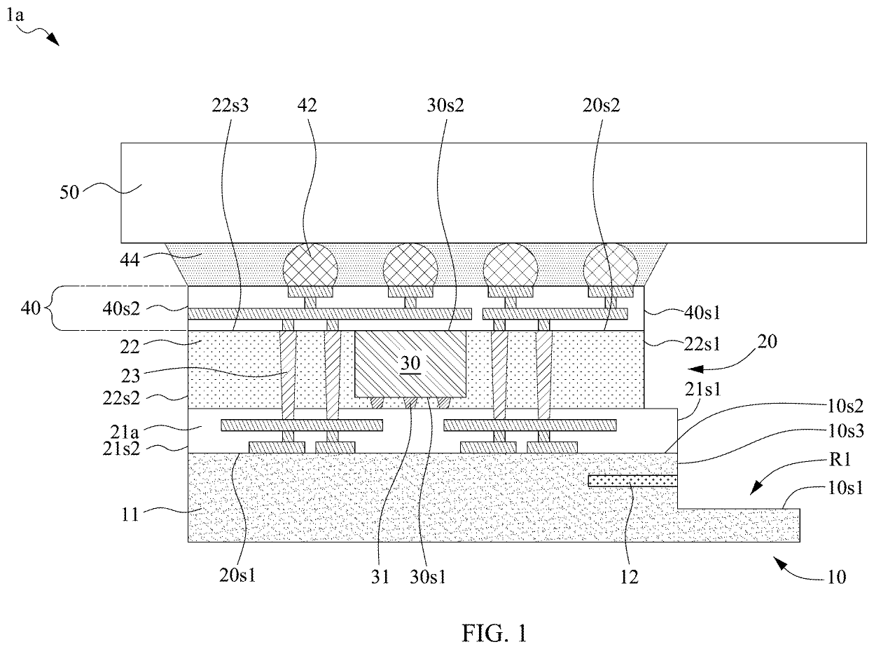

FIG. 1 illustrates a cross-sectional view of an optoelectronic package 1a according to some embodiments of the present disclosure. In some embodiments, the optoelectronic package 1a may include a photonic component 10, a connection structure 20, an electronic component 30, a redistribution structure 40, and a circuit structure 50.

The photonic component 10 can be configured to process, receive, and/or transmit optical signals. The photonic component 10 can convert the optical signals to electric signals or convert the electric signals to optical signals. The photonic component 10 can include, but is not limited to, a photonic integrated circuit (PIC). The photonic component 10 may include a surface 10s1, a surface 10s2, and a surface 10s3. The surface 10s1 may be located at a horizontal level lower than that of the surface 10s2. The surface 10s3 (or a lateral surface) may extend between the surfaces 10s1 and 10s2. In some embodiments, the surfaces 10s1 and 10s3 may define a recess region R1 recessed from the surface 10s2. The surface 10s1 may serve as a bottom of the recess region R1. In some embodiments, the surface 10s2 may serve as an active surface of the photonic component 10. A plurality of terminals (not annotated) may be disposed on or adjacent to the surface 10s2 of the photonic component 10 for transmitting signals. The terminal of the photonic component 10 may include, for example, a conductive pad or other suitable elements.

The photonic component 10 may include a substrate 11 (or carrier) and a waveguide 12. The substrate 11 may include a semiconductor substrate. The substrate 11 may include silicon (Si) or germanium (Ge) in a single crystal form, a polycrystalline form, or an amorphous form. Although not shown in FIG. 1, the substrate 11 may include one or more active elements, passive elements, and conductive traces disposed therein. The active element may include a transistor, diode, or other active elements. The transistor may include bipolar junction transistor, metal-oxide-semiconductor field-effect transistor (MOSFET), junction gate field-effect transistor (JFET) and other transistors. The diode may include Zener diode, photodiode, Schottky diode and other diodes. The passive element may include a capacitor, resistor, inductor or other suitable passive elements.

The waveguide 12 may be embedded in the substrate 11. In some embodiments, the waveguide 12 may be exposed from the surface 10s3 of the photonic component 10. The waveguide 12 may be configured to receive and transmit optical signals (e.g., light). In some embodiments, the waveguide 12 may serve as an optical channel, which may be configured to transmit optical signals. The waveguide 12 may include a semiconductor material. For example, the waveguide 12 may include or be composed of silicon, silicon nitride, or other suitable materials. In some embodiments, the photonic component 10 may further include a cladding layer (not shown) at least partially enclosing the waveguide 12. The cladding layer may include or be composed of oxide, such as silicon oxide (SiO₂), yttrium oxide (Y₂O₃), aluminum oxide or other suitable materials. In some embodiments, the refractive index of the material of the waveguide 12 may be greater than that of the cladding layer.

In some embodiments, the connection structure 20 may be disposed over the surface 10s2 of the photonic component 10. In some embodiments, the connection structure 20 may be in contact with the surface 10s2 of the photonic component 10. The connection structure 20 may be configured to connect the photonic component 10 to an electrically conductive feature, such as a redistribution structure, a circuit board, or other suitable electrically conductive features. In some embodiments, the connection structure 20 may include a redistribution structure 21a, an encapsulant 22, and conductive pillars 23.

In some embodiments, the redistribution structure 21a may be located on the surface 10s2 of the photonic component 10. In some embodiments, the redistribution structure 21a may be a fan-out structure. The redistribution structure 21a may include a conductive pad(s), a trace(s), a via(s), or other interconnection(s) embedded in at least one dielectric layer. A plurality of terminals (not annotated) may be disposed on or adjacent to two opposite surfaces of the redistribution structure 21a for transmitting and/or receiving signals. The terminal of the redistribution structure 21a may be, for example, a conductive pad. In some embodiments, the dielectric layer of the redistribution structure 21a may include polyimide (PI), polybenzoxazole (PBO), benzocyclobutene (BCB), or other suitable materials.

In some embodiments, the redistribution structure 21a may be in contact with the surface 10s2 of the photonic component 10. For example, the terminal of the redistribution structure 21a may be in contact with the terminal of the photonic component 10. In some embodiments, the redistribution structure 21a has a first surface (or a lower surface; not annotated) in contact with the surface 10s2 of the photonic component 10 and has a second surface (or an upper surface; not annotated) opposite to the first surface and in contact with the encapsulant 22 of the connection structure 20. In some embodiments, no conductive elements are disposed between the redistribution structure 21a and the photonic component 10. In some embodiments, no conductive elements are disposed between the terminal of the redistribution structure 21a and the terminal of the photonic component 10. The said conductive element may include, but is not limited to, a bump made of solder materials, a conductive pillar or other conductive elements surrounded by an underfill or by an encapsulant. In some embodiments, no underfill and/or molding compound is disposed between the redistribution structure 21a and the photonic component 10.

The redistribution structure 21a may include a surface 21s1 (or a lateral surface) extending between the first surface (or a lower surface; not annotated) and the second surface (or an upper surface; not annotated) of the redistribution structure 21a. In some embodiments, the surface 21s1 of the redistribution structure 21a is substantially coplanar with the surface 10s3 of the photonic component 10. The redistribution structure 21a may include a surface 21s2 (or a lateral surface) opposite to the surface 21s1.

The encapsulant 22 may be disposed over the upper surface of the redistribution structure 21a. The encapsulant 22 may include insulation or dielectric material. In some embodiments, the encapsulant 22 may be made of molding material that may include, for example, a Novolac-based resin, an epoxy-based resin, a silicone-based resin, or other another suitable encapsulant. Suitable fillers may also be included, such as powdered SiO₂. The encapsulant 22 may include a surface 22s1 (or a lateral surface) and a surface 22s2 (or a lateral surface) opposite to the surface 22s1. In some embodiments, the surface 22s1 of the encapsulant 22 may be noncoplanar with the surface 21s1 of the redistribution structure 21a. In some embodiments, a portion of the upper surface of the redistribution structure 21a may be exposed from the encapsulant 22. In some embodiments, the surface 22s1 of the encapsulant 22 may be noncoplanar with the surface 10s3 of the photonic component 10. In some embodiments, the surface 22s2 of the encapsulant 22 may be substantially coplanar with the surface 21s2 of the redistribution structure 21a. The encapsulant 22 may have a surface 22s3 (or an upper surface) facing the redistribution structure 40.

The conductive pillar 23 may be disposed over the upper surface of the redistribution structure 21a. The conductive pillar 23 may be disposed adjacent to a lateral surface (not annotated) of the electronic component 30. In some embodiments, the conductive pillar 23 may penetrate a portion of the dielectric layer of the redistribution structure 21a to be electrically connected to the terminal of the redistribution structure 21a. In some embodiments, the conductive pillar 23 may penetrate the encapsulant 22. In some embodiments, the conductive pillar 23 may be tapered. In some embodiments, the conductive pillar 23 may be tapered toward the photonic component 10 or the redistribution structure 21a. The conductive pillar 23 may include a conductive material(s), such as copper (Cu), tungsten (W), ruthenium (Ru), iridium (Ir), nickel (Ni), osmium (Os), rhodium (Rh), aluminum (Al), molybdenum (Mo), cobalt (Co), alloys thereof, combinations thereof or any metallic materials.

The connection structure 20 may have a surface 20s1 (or a lower surface) and a surface 20s2 (or an upper surface) opposite to the surface 20s1. In some embodiments, the lower surface of the redistribution structure 21a may serve as the surface 20s1 of the connection structure 20. In some embodiments, the surface 22s3 (e.g., upper surface) of the encapsulant 22 may serve as the surface 20s2 of the connection structure 20.

In some embodiments, the electronic component 30 may be embedded in the encapsulant 22. The electronic component 30 may include, for example, an electronic integrated circuit (EIC). The electronic component 30 may be configured to process, receive, and/or transmit electrical signals from other components, such as the photonic component 10. The electronic component 30 may include a transceiver including a physical-layer circuit or a physical-layer interface portion (normally abbreviated as “PHY”), which connects a physical medium through which data is conveyed to and from the electronic component 30. In some arrangements, the electronic component 30 may include a Serializer-Deserializer (SERDES) die. The SERDES die may be used in high speed communications to convert data between serial data and parallel interfaces in order to minimize the number of I/O pins and interconnects. The electronic component 30 may be electrically connected to the photonic component 10. The electronic component 30 may include a surface 30s1 and a surface 30s2 opposite to the surface 30s1. The surface 30s1 of the electronic component 30 may face the redistribution structure 21a. In some embodiments, the surface 30s1 may be an active surface of the electronic component 30, and the surface 30s2 may be a backside surface of the electronic component 30. In some embodiments, the electronic component 30 may be electrically connected to or in contact with the redistribution structure 21a by electrical connections 31. In some embodiments, the electrical connection 31 may be disposed on the surface 30s1 of the electronic component 30. The electrical connection 31 may include a conductive pad, a bump (e.g., solder element), a conductive pillar, or other suitable conductive elements.

In some embodiments, the redistribution structure 40 may be disposed over the connection structure 20 or the encapsulant 22 of the connection structure 20. In some embodiments, the redistribution structure 40 may be in contact with the connection structure 20 or the encapsulant 22 of the connection structure 20. In some embodiments, the redistribution structure 40 may be in contact with the surface 30s2 of the electronic component 30. In some embodiments, the redistribution structure 40 may be electrically connected to the redistribution structure 21a by the conductive pillar 23. The redistribution structure 40 may be a fan-out structure. The redistribution structure 40 may include a conductive pad(s), a trace(s), a via(s), or other interconnection(s) embedded in at least one dielectric layer. The redistribution structure 40 may include a surface 40s1 (or a lateral surface) and a surface 40s2 (or a lateral surface) opposite to the surface 40s1. In some embodiments, the surface 40s1 of the redistribution structure 40 may be substantially coplanar with the surface 22s1 of the connection structure 20. In some embodiments, the surface 40s1 of the redistribution structure 40 may be noncoplanar with the surface 21s1 of the redistribution structure 21a. In some embodiments, the surface 40s2 of the redistribution structure 40 may be substantially coplanar with the surface 22s2 of the encapsulant 22. In some embodiments, the surface 40s2 of the redistribution structure 40 may be substantially coplanar with the surface 21s2 of the redistribution structure 21a.

The optoelectronic package 1a may further include electrical connections 42 and an underfill 44. The electrical connection 42 may be disposed over an upper surface (not annotated) of the redistribution structure 40. The electrical connection 42 may be configured to electrically connect the redistribution structure 40 and the circuit structure 50. In some embodiments, the electrical connection 42 may include a solder material, such as alloys of gold and tin solder or alloys of silver and tin solder.

The underfill 44 may surround the electrical connections 42. The underfill 44 may be in contact with the redistribution structure 40. The underfill 44 may be in contact with the circuit structure 50. The underfill 44 may include, for example, epoxy-based resins or other suitable materials.

The circuit structure 50 may be disposed over an upper surface of the redistribution structure 40. In some embodiments, the circuit structure 50 may be electrically connected to the redistribution structure 40 through electrical connections 42. The circuit structure 50 may include a printed circuit board, such as a paper-based copper foil laminate, a composite copper foil laminate, or a polymer-impregnated glass-fiber-based copper foil laminate.

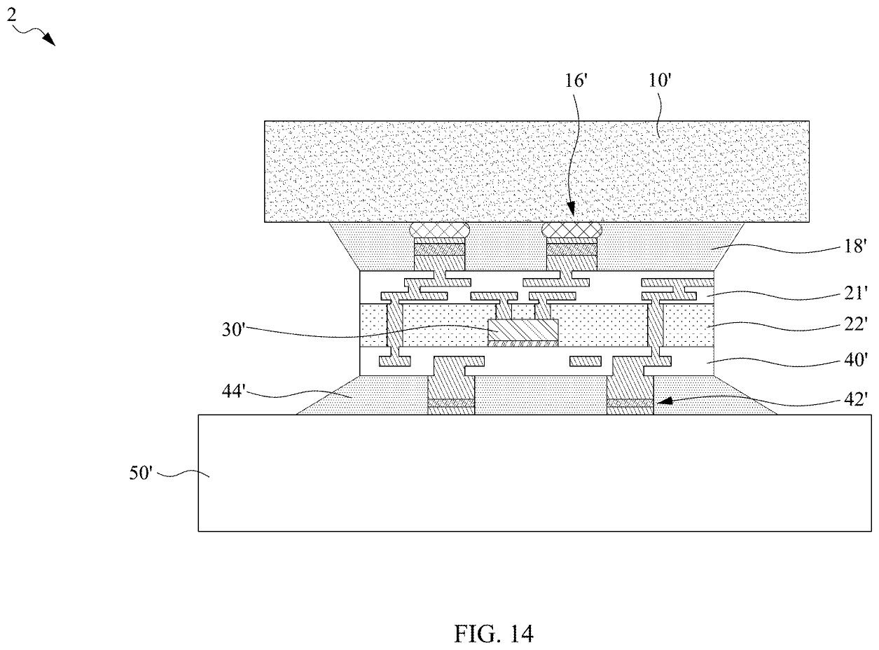

In this embodiment, the redistribution structure 21a may be directly formed on the active surface (e.g., surface 10s2) of the photonic component 10 during manufacturing processes. Since the substrate 11 of the photonic component 10 is relatively thick, the whole structure of the redistribution structure 21a and the photonic component 10 may have a relatively small warpage, which may prevent manufacturing problems, such as solder skip, of a comparative example. The comparative example will be discussed in detail in FIG. 14.

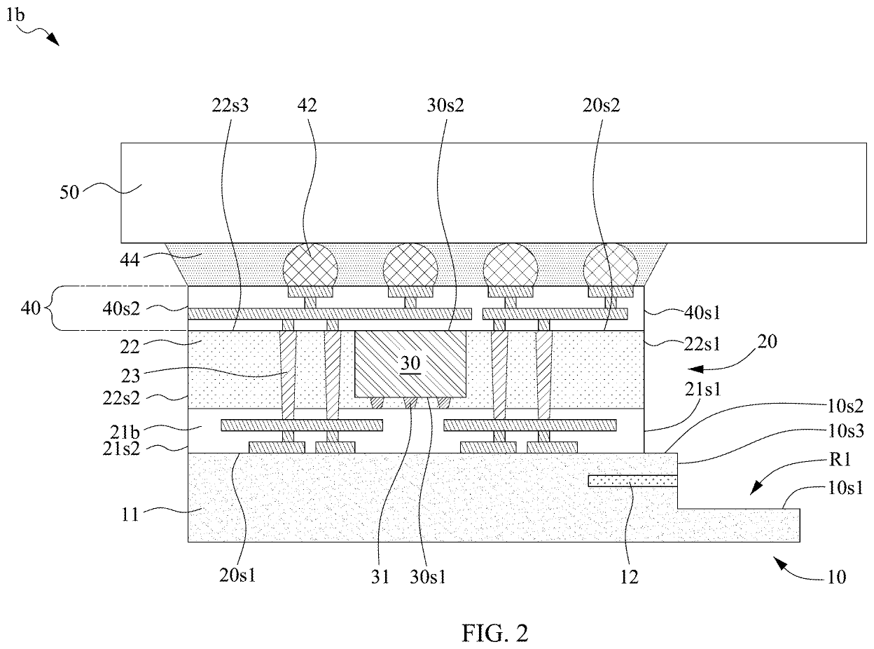

FIG. 2 illustrates a cross-sectional view of an optoelectronic package 1b according to some embodiments of the present disclosure. The optoelectronic package 1b is similar to the optoelectronic package 1a as shown in FIG. 1, and the differences therebetween are described below.

In some embodiments, the optoelectronic package 1b may include a redistribution structure 21b. In some embodiments, the surface 21s1 of the redistribution structure 21b may be noncoplanar with the surface 10s3 of the photonic component 10. In some embodiments, the surface 21s1 of the redistribution structure 21b may be substantially coplanar with the surface 22s1 of the encapsulant 22. In some embodiments, the surface 21s1 of the redistribution structure 21b may be substantially coplanar with the surface 40s1 of the redistribution structure 40.

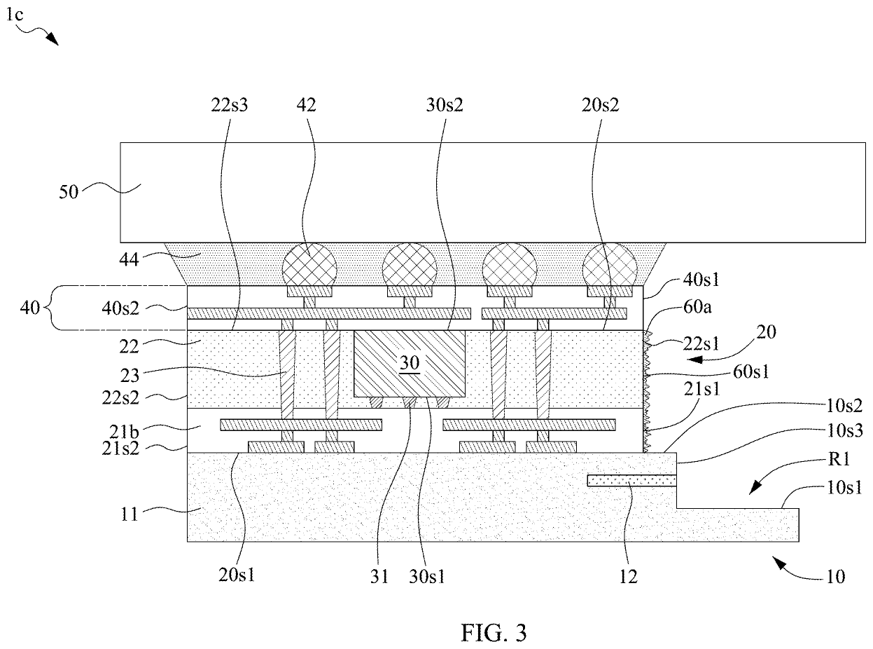

FIG. 3 illustrates a cross-sectional view of an optoelectronic package 1c according to some embodiments of the present disclosure. The optoelectronic package 1c is similar to the optoelectronic package 1b as shown in FIG. 2, and the differences therebetween are described below.

In some embodiments, the optoelectronic package 1c may further include a dummy residue 60a. In some embodiments, the dummy residue 60a may be a residue generated in manufacturing processes. In some embodiments, the dummy residue 60a may be a residue of a component used in manufacturing processes and said component is at least partially removed from a final product. In some embodiments, the dummy residue 60a may be a residue of a component after removal, and the dummy residue 60a may have a relatively rough surface and/or uneven thickness due to the removal technique. The method for removing the dummy die can be, for example, an etching technique, a laser drilling technique, a pick-up technique or any other suitable technique, or a combination thereof. In some embodiments, the dummy residue 60a may include semiconductor material, such as silicon, germanium, silicon-germanium, or other suitable materials. In some embodiments, the dummy residue 60a may include a glass, a ceramic material, or other suitable materials. The dummy residue 60a may have a surface 60s1. In some embodiments, the surface 60s1 of the dummy residue 60a may have a roughness greater than a roughness of the surface 10s3 of the recess region R1 of the photonic component 10.

In some embodiments, the dummy residue 60a may cover the surface 21s1 of the redistribution structure 21b. In some embodiments, the dummy residue 60a may be in contact with the surface 21s1 of the redistribution structure 21b. In some embodiments, the dummy residue 60a may cover the surface 22s1 of the encapsulant 22. In some embodiments, the dummy residue 60a may be in contact with the surface 22s1 of the encapsulant 22. In some embodiments, the surface 40s1 of the redistribution structure 40 is not covered by the dummy residue 60a. In some embodiments, the surface 10s3 of the photonic component 10 is not covered by the dummy residue 60a. Although FIG. 3 illustrates that the surface 21s1 of the redistribution structure 21b and the surface 22s1 of the encapsulant 22 are entirely covered by the dummy residue 60a, a portion of the surface 21s1 of the redistribution structure 21b and/or the surface 22s1 of the encapsulant 22 may be exposed from the dummy residue 60a in other embodiments.

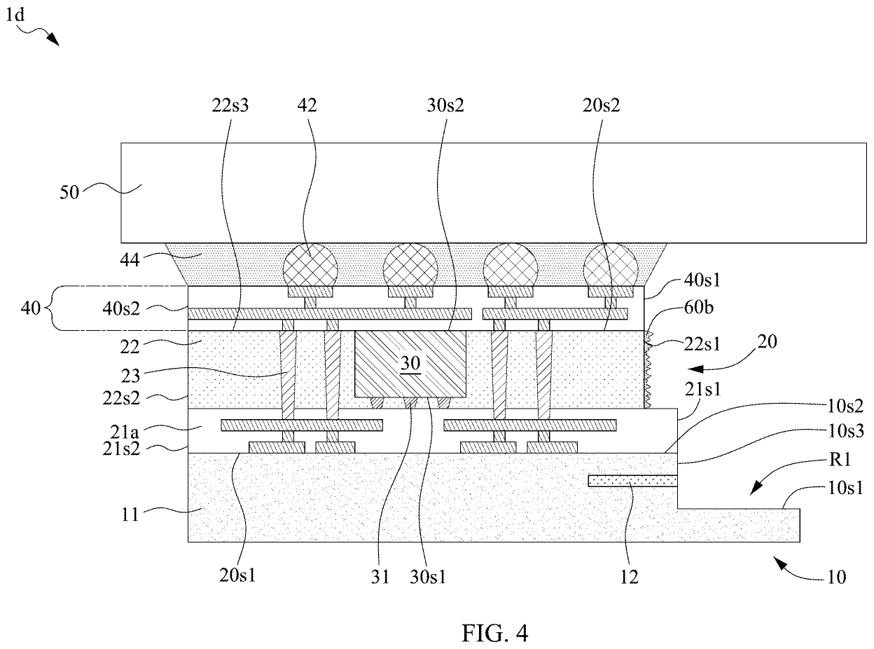

FIG. 4 illustrates a cross-sectional view of an optoelectronic package 1d according to some embodiments of the present disclosure. The optoelectronic package 1d is similar to the optoelectronic package 1a as shown in FIG. 1, and the differences therebetween are described below.

In some embodiments, the optoelectronic package 1d may further include a dummy residue 60b. The material of the dummy residue 60b may be the same as or similar to that of the dummy residue 60a. In some embodiments, the dummy residue 60b may cover the surface 22s1 of the encapsulant 22. In some embodiments, the dummy residue 60b may be in contact with the surface 22s1 of the encapsulant 22. In some embodiments, the surface 21s1 of the redistribution structure 21a is not covered by the dummy residue 60b. In some embodiments, the surface 10s3 of the photonic component 10 is not covered by the dummy residue 60b. In some embodiments, the surface 40s1 of the redistribution structure 40 is not covered by the dummy residue 60b.

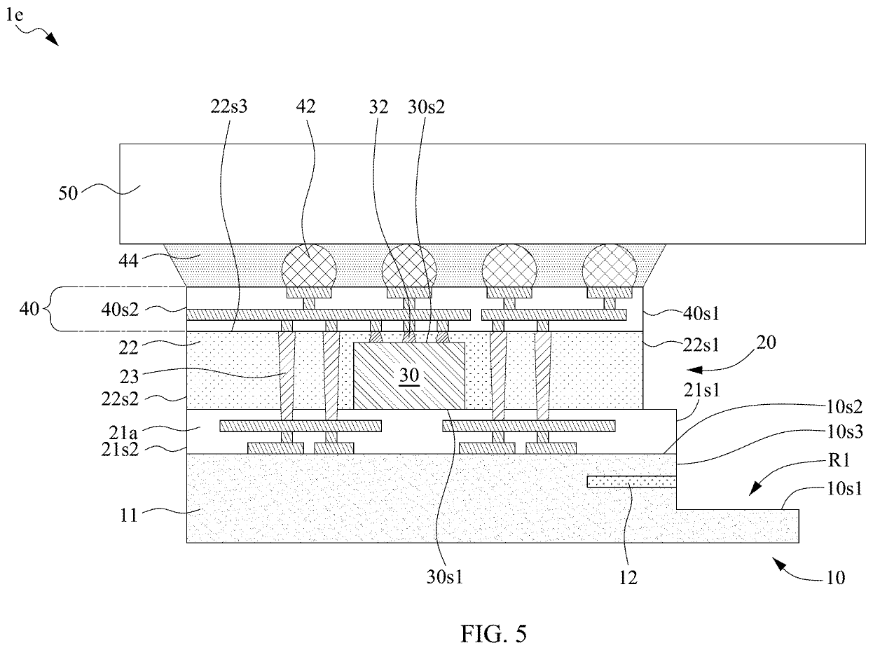

FIG. 5 illustrates a cross-sectional view of an optoelectronic package 1e according to some embodiments of the present disclosure. The optoelectronic package 1e is similar to the optoelectronic package 1a as shown in FIG. 1, and the differences therebetween are described below.

In some embodiments, the surface 30s1 of the electronic component 30 may be a backside surface, and the surface 30s2 of the electronic component 30 may be an active surface. The electronic component 30 may be electrically connected to the redistribution structure 40 through electrical connections 32. In some embodiments, the electrical connection 32 may be disposed over the surface 30s2 of the electronic component 30. The backside surface of the electronic component 30 faces the surface 10s2 of the photonic component 10. In some embodiments, the backside surface of the electronic component 30 is in contact with the upper surface of the redistribution structure 21a. In some embodiments, the backside surface of the electronic component 30 is attached to the upper surface of the redistribution structure 21a via a die attach film (DAF).

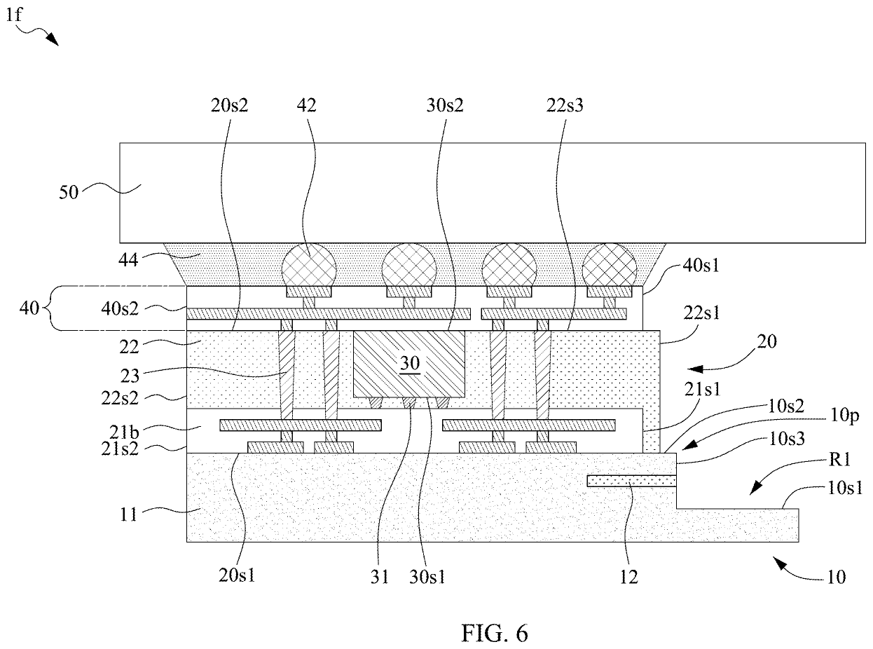

FIG. 6 illustrates a cross-sectional view of an optoelectronic package 1f according to some embodiments of the present disclosure. The optoelectronic package 1f is similar to the optoelectronic package 1b as shown in FIG. 2, and the differences therebetween are described below.

In some embodiments, the encapsulant 22 may cover the surface 21s1 of the redistribution structure 21b. In some embodiments, the encapsulant 22 may further extend to cover the surface 21s1 of the redistribution structure 21b. In some embodiments, the encapsulant 22 may be in contact with the surface 21s1 of the redistribution structure 21b. In some embodiments, the surface 22s1 of the encapsulant 22 may be noncoplanar with the surface 40s1 of the redistribution structure 40. In some embodiments, the surface 22s1 of the encapsulant 22 may be in contact with the surface 10s2 of the photonic component 10. In some embodiments, a portion of the surface 22s3 of the encapsulant 22 may be exposed from the redistribution structure 40. In some embodiments, the surface 10s2 of the photonic component 10 and the surface 22s1 of the encapsulant 22 collectively define a stepped structure 10p.

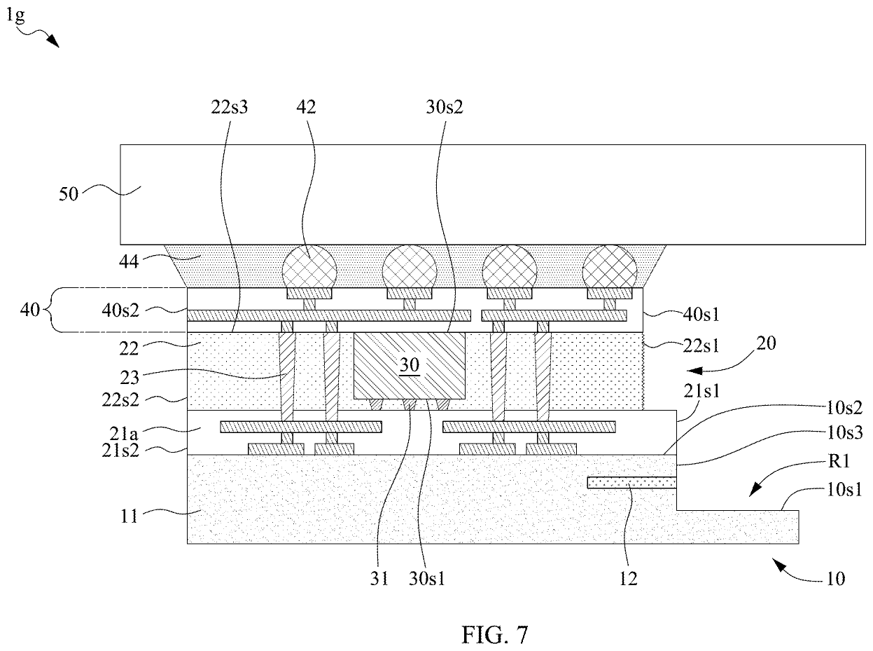

FIG. 7 illustrates a cross-sectional view of an optoelectronic package 1g according to some embodiments of the present disclosure. The optoelectronic package 1g is similar to the optoelectronic package 1a as shown in FIG. 1, and the differences therebetween are described below.

In some embodiments, the surface 22s1 of the encapsulant 22 may have a relatively large roughness. In some embodiments, the surface 22s1 of the encapsulant 22 may be etched by an etching technique during manufacturing processes so that the surface 22s1 of the encapsulant 22 may have a relatively large roughness. In some embodiments, the roughness of the surface 22s1 of the encapsulant 22 may be different from that of the surface 40s1 of the redistribution structure 40 or that of the surface 22s2 of the encapsulant 22. In some embodiments, the roughness of the surface 22s1 of the encapsulant 22 may be greater than that of the surface 40s1 of the redistribution structure 40 or that of the surface 22s2 of the encapsulant 22.

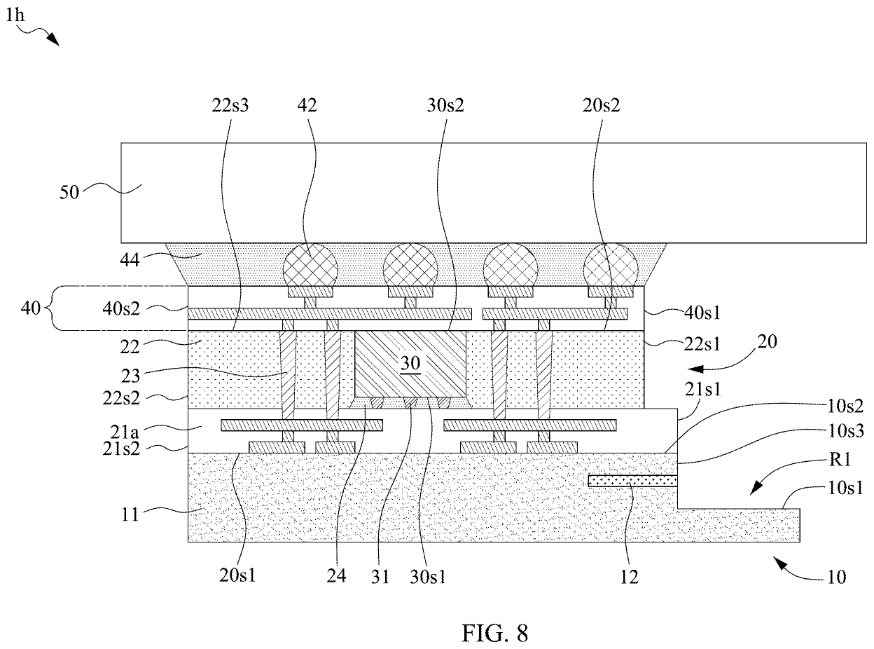

FIG. 8 illustrates a cross-sectional view of an optoelectronic package 1h according to some embodiments of the present disclosure. The optoelectronic package 1h is similar to the optoelectronic package 1a as shown in FIG. 1, and the differences therebetween are described below.

In some embodiments, the optoelectronic package 1h may further include an underfill 24. The underfill 24 may surround the electrical connections 31. The underfill 24 may be in contact with the redistribution structure 21a. The underfill 24 may include, for example, epoxy-based resins or other suitable materials.

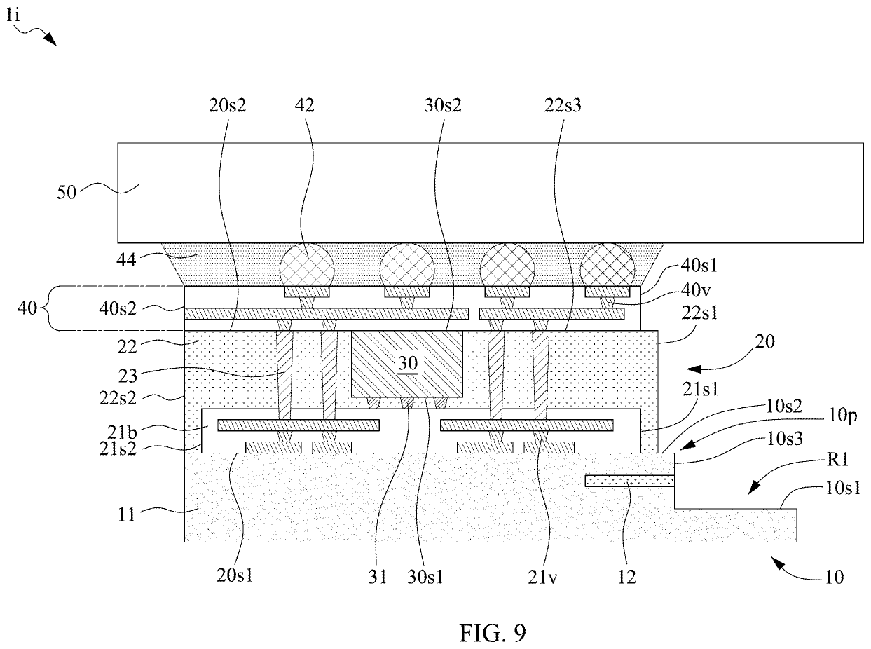

FIG. 9 illustrates a cross-sectional view of an optoelectronic package 1i according to some embodiments of the present disclosure. The optoelectronic package 1i is similar to the optoelectronic package 1f as shown in FIG. 6, and the differences therebetween are described below.

In some embodiments, the encapsulant 22 may cover the surface 21s2 of the redistribution structure 21b. In some embodiments, the redistribution structure 21b may have a via 21v. In some embodiments, the via 21v may be tapered toward the photonic component 10. In some embodiments, the redistribution structure 40 may have a via 40v. In some embodiments, the via 40v may be tapered toward the electronic component 30.

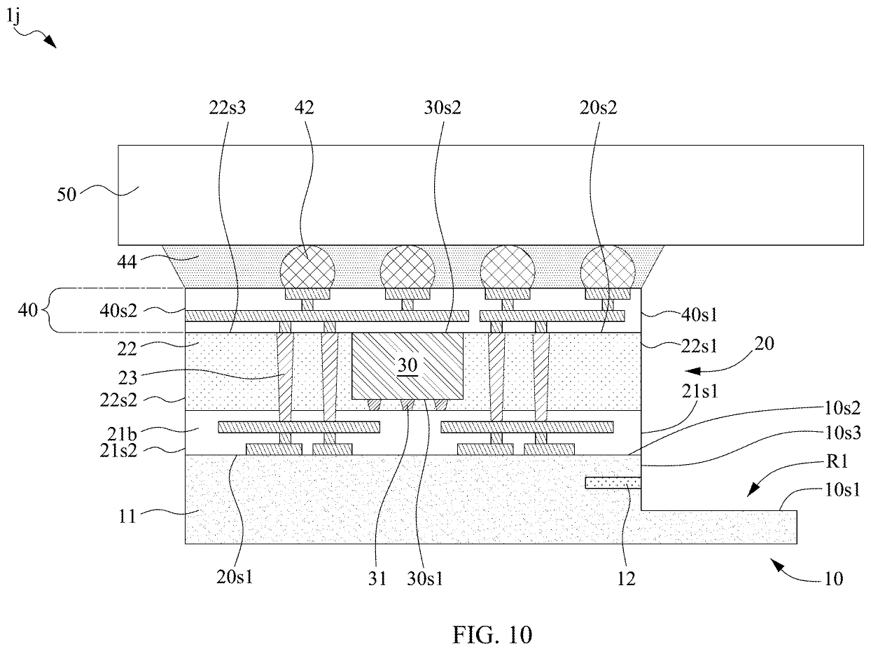

FIG. 10 illustrates a cross-sectional view of an optoelectronic package 1j according to some embodiments of the present disclosure. The optoelectronic package 1j is similar to the optoelectronic package 1a as shown in FIG. 1, and the differences therebetween are described below.

In some embodiments, the surface 10s3 of the photonic component 10 may be coplanar with the surface 21s1 of the redistribution structure 21b. In some embodiments, the surface 10s3 of the photonic component 10 may be coplanar with the surface 22s1 of the encapsulant 22. In some embodiments, the surface 21s1 of the redistribution structure 21b may be coplanar with the surface 22s1 of the encapsulant 22.

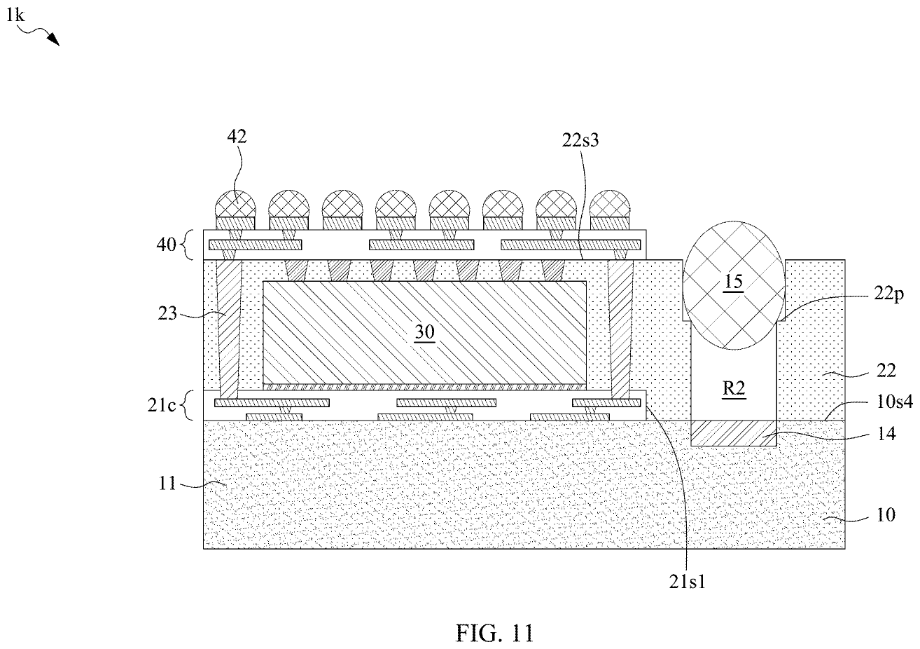

FIG. 11 illustrates a cross-sectional view of an optoelectronic package 1k according to some embodiments of the present disclosure.

In some embodiments, the photonic component 10 may have a grating coupler 14. In some embodiments, the grating coupler 14 may be configured to transmit optical signals to the waveguide (not shown in this figure) embedded in the substrate 11. In some embodiments, the grating coupler 14 may be exposed from a surface 10s4 (or an upper surface) of the photonic component 10.

A redistribution structure 21c may be disposed over the surface 10s4 of the photonic component 10. In some embodiments, the encapsulant 22 may define a recess region R2 exposing the grating coupler 14. In some embodiments, the encapsulant 22 may have a stepped-structure 22p within the recess region R2 such that the lower portion of the recess region R2 has a horizontal dimension smaller than that of the upper portion of the recess region R2.

In some embodiments, the optoelectronic package 1k may further include a collimator element 15. The collimator element 15 may be configured to allow optical signals, such as light, to focus on the grating coupler 14. In some embodiments, the collimator element 15 may be surrounded by the encapsulant 22. In some embodiments, the collimator element 15 may be supported by the stepped-structure 22p of the encapsulant 22. In some embodiments, the collimator element 15 may include a lens or other suitable elements. The collimator element 15 may have any suitable profile to make optical signals focus on the grating coupler 14.

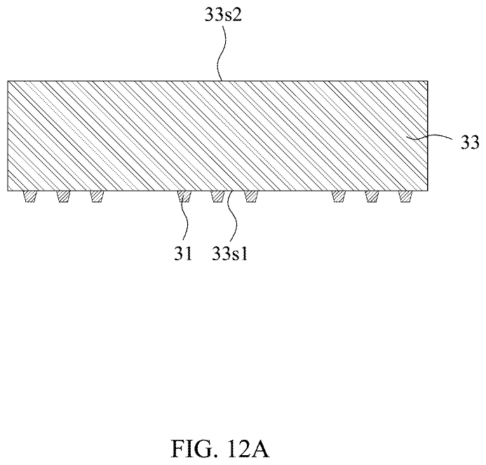

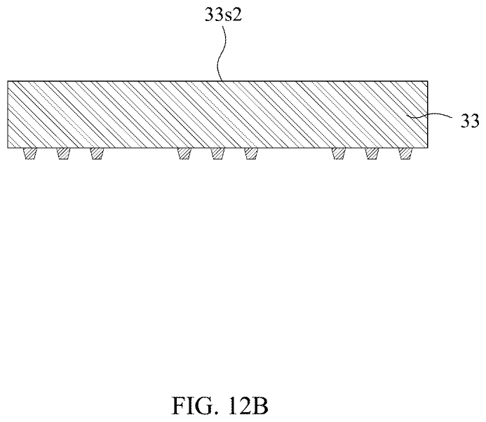

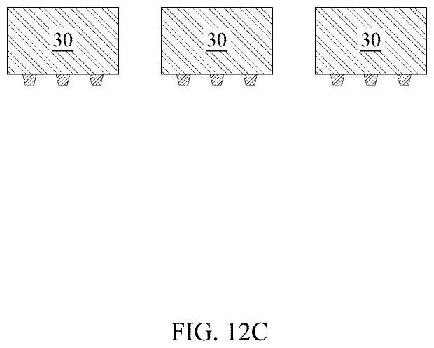

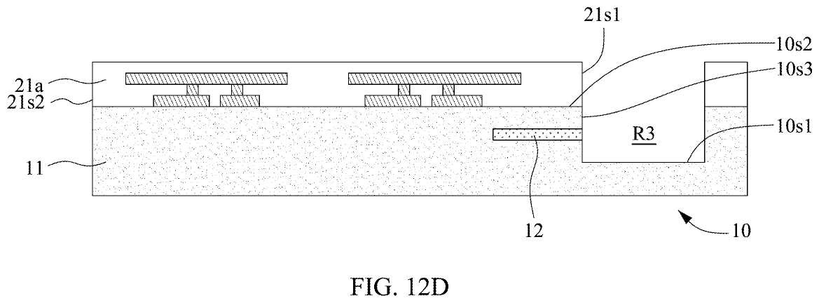

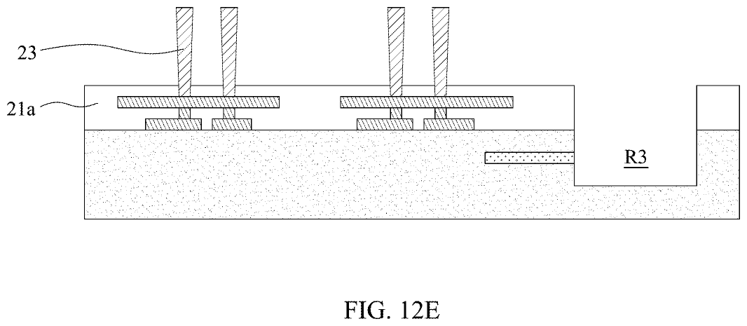

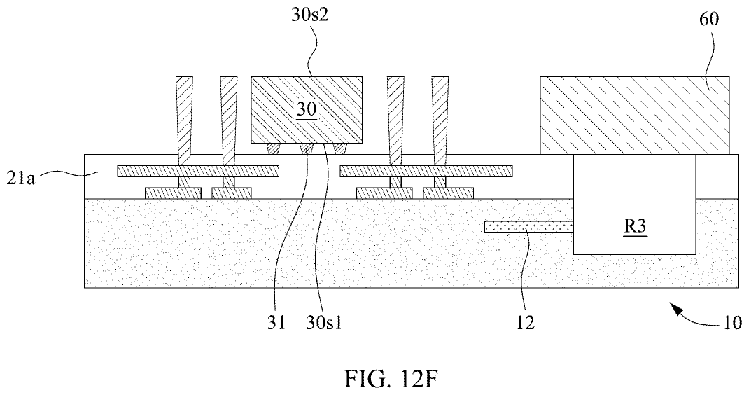

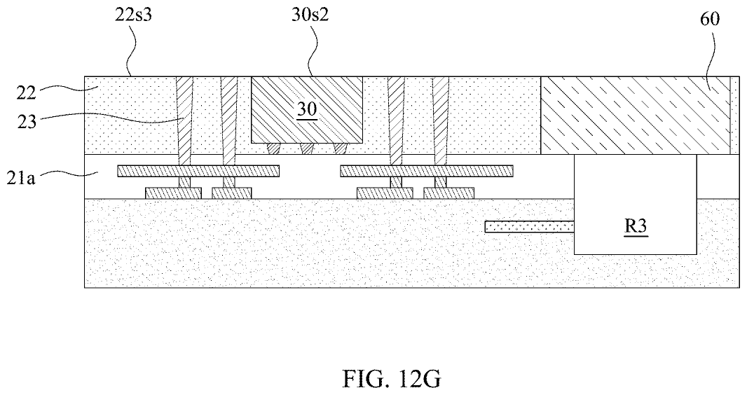

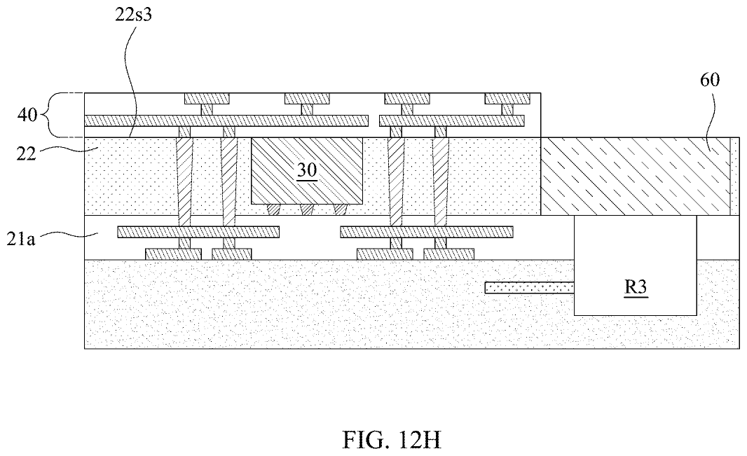

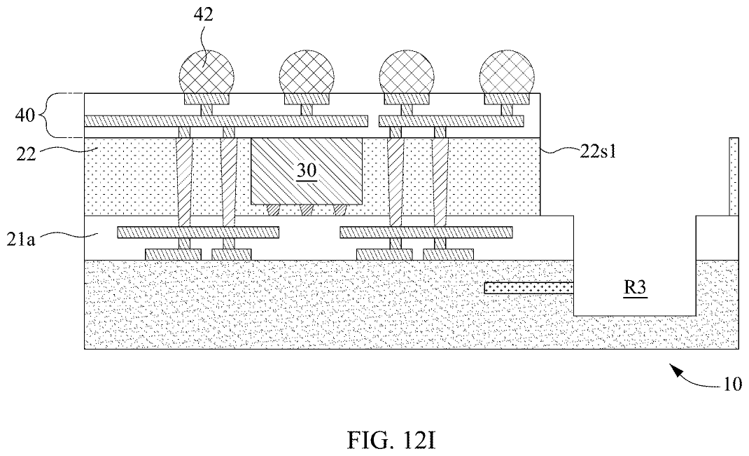

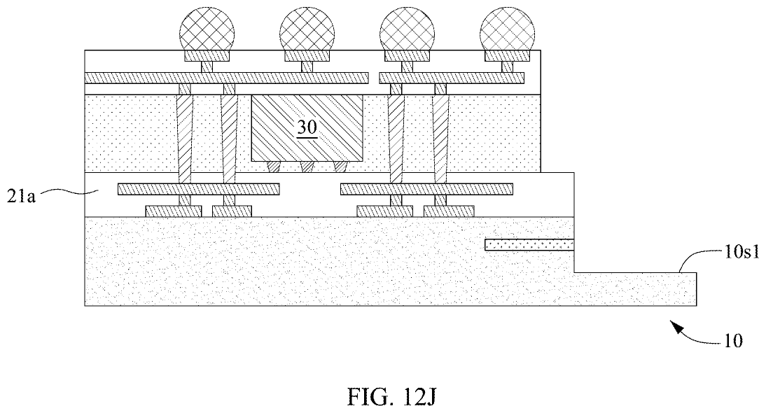

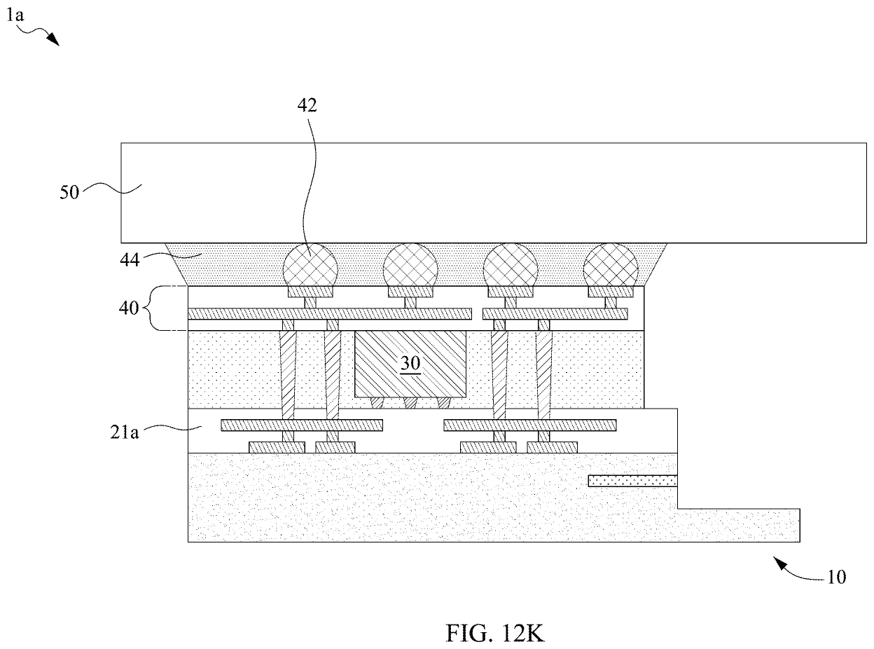

FIG. 12A, FIG. 12B, FIG. 12C, FIG. 12D, FIG. 12E, FIG. 12F, FIG. 12G, FIG. 12H, FIG. 12I, FIG. 12J and FIG. 12K illustrate various stages of an example of a method for manufacturing an optoelectronic package according to some embodiments of the present disclosure.

Referring to FIG. 12A, a wafer 33 may be provided. The wafer 33 may include a plurality of units, which may be utilized to form chips, such as an EIC, after the wafer 33 is singulated. The wafer 33 may have a surface 33s1 and a surface 33s2 opposite to the surface 33s1. A plurality of electrical connections 31 may be formed on the surface 33s1 of the wafer 33.

Referring to FIG. 12B, a grinding technique may be performed on the surface 33s2 of the wafer 33 to reduce the thickness of the wafer 33.

Referring to FIG. 12C, the wafer 33 may be singulated to produce a plurality of electronic components 30.

Referring to FIG. 12D, a photonic component 10 may be provided. A redistribution structure 21a may be formed on the surface 10s2 of the photonic component 10. In some embodiments, an etching technique may be performed to remove a portion of the redistribution structure 21a and a portion of a substrate 11 of the photonic component 10 to define a recess region R3 recessed from an upper surface of the redistribution structure 21a, and the surface 21s1 of the redistribution structure 21a may be substantially coplanar with the surface 10s3 of the photonic component 10. A waveguide 12 may be exposed from the recess region R3. The surface 10s1 may serve as the bottom of the recess region R3 after the etching technique is performed. In some embodiments, before the redistribution structure 21a is formed, the etching technique may be performed to remove a portion of the substrate 11 of the photonic component 10 to define the recess region R3 and then the redistribution structure 21a is formed on the surface 10s2 of the photonic component 10 with an opening exposing the recess region R3. Further, the area of the surface 10s2 of the photonic component 10 for forming the redistribution structure 21a may be predetermined. In some embodiments, a portion of the surface 10s2 of the photonic component 10 may be exposed from the redistribution structure 21a.

Referring to FIG. 12E, a plurality of conductive pillars 23 may be formed over the redistribution structure 21a. In some embodiments, a photoresist layer (not shown) may be formed on the redistribution structure 21a. The photoresist layer may be patterned to form a plurality of openings, each of which is tapered toward the redistribution structure 21a. Next, a seed layer may be formed within the openings of the photoresist layer, and a conductive material may be formed on the seed layer to form the conductive pillars 23. The photoresist layer may be removed after the conductive pillars 23 are formed.

Referring to FIG. 12F, the electronic component 30 may be disposed on the redistribution structure 21a. In some embodiments, the electronic component 30 may be disposed on and electrically connected to the redistribution structure 21a through the electrical connections 31. In some embodiments, the surface 30s1 of the electronic component 30 may be an active surface, and the surface 30s2 of the electronic component 30 may be a backside surface. A dummy die 60 may be provided to cover the recess region R3 of the photonic component 10. The dummy die 60 may be configured to protect the waveguide 12 from being contaminated in subsequent manufacturing processes. In some embodiments, the dummy die 60 may include semiconductor material, such as silicon, germanium, silicon-germanium, or other suitable materials. In some embodiments, the dummy die 60 may include a glass, a ceramic material, or other suitable materials. In some embodiments, the dummy die 60 may be disposed over the upper surface of the redistribution structure 21a.

Referring to FIG. 12G, an encapsulant 22 may be formed over the redistribution structure 21a. In some embodiments, a grinding technique may be performed so that the surface 22s3 of the encapsulant 22, the upper surface (not annotated) of the conductive pillar 23, and/or the surface 30s2 of the electronic component 30 may be substantially coplanar. In some embodiments, the encapsulant 22 may be in contact with the dummy die 60. The dummy die 60 prevents the material of the encapsulant from entering the recess region R3.

Referring to FIG. 12H, a redistribution structure 40 may be formed over the surface 22s3 of the encapsulant 22. The redistribution structure 40 may cover the electronic component 30. In some embodiments, the dummy die 60 is not covered by the redistribution structure 40. Although FIG. 12H illustrates that the surface 22s3 of the encapsulant 22 is completely covered by the redistribution structure 40, a portion of the surface 22s3 of the encapsulant 22 may be exposed from the redistribution structure 40 in other embodiments.

Referring to FIG. 12I, a plurality of electrical connections 42 may be formed over the redistribution structure 40. In some embodiments, the dummy die 60 may be removed to expose the recess region R3 of the photonic component 10. In some embodiments, the dummy die 60 may be removed by an etching technique, a laser drilling technique, or a pick-up technique, or any other suitable technique, or a combination thereof. It is contemplated that the laser drilling technique may be performed to remove a portion of the encapsulant 22 so that the surface 22s1 of the encapsulant 22 may have a relatively great roughness in other embodiments. It is contemplated that a residue of the dummy die 60 (e.g., dummy residue 60a as shown in FIG. 3) may remain on the surface 22s1 of the encapsulant 22 after the laser drilling technique is performed.

Referring to FIG. 12J, the photonic component 10 may be singulated. A saw may be utilized to cut the photonic component 10 from the surface 10s1 of the photonic component 10.

Referring to FIG. 12K, a circuit structure 50 may be provided. The resulting structure of FIG. 12J may be attached and electrically connected to the circuit structure 50 through the electrical connections 42. An underfill 44 may be used to encapsulate the electrical connections 42. As a result, an optoelectronic package, such as the optoelectronic package 1a as shown in FIG. 1, may be produced.

In this embodiment, the redistribution structure 21a may be formed on the photonic component 10 rather than on the electronic component 30. The photonic component 10 is relatively thick in comparison with the singulated electronic component 30. Therefore, in comparison with a comparative example where a redistribution structure is formed on the EIC, the intermediate structure of the photonic component 10 and the redistribution structure 21a may have a relatively small warpage, which thereby facilitates subsequent processes.

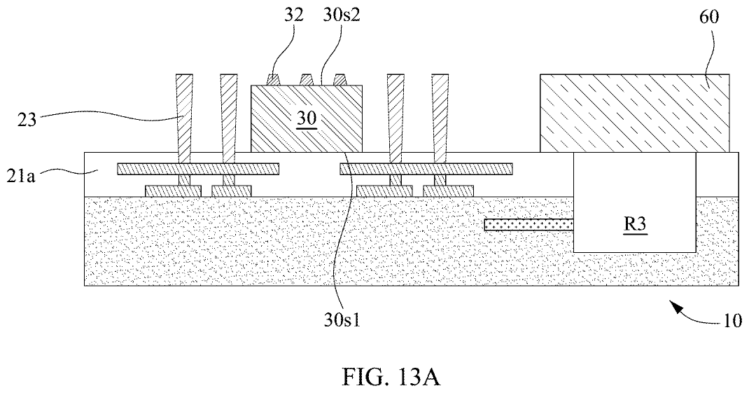

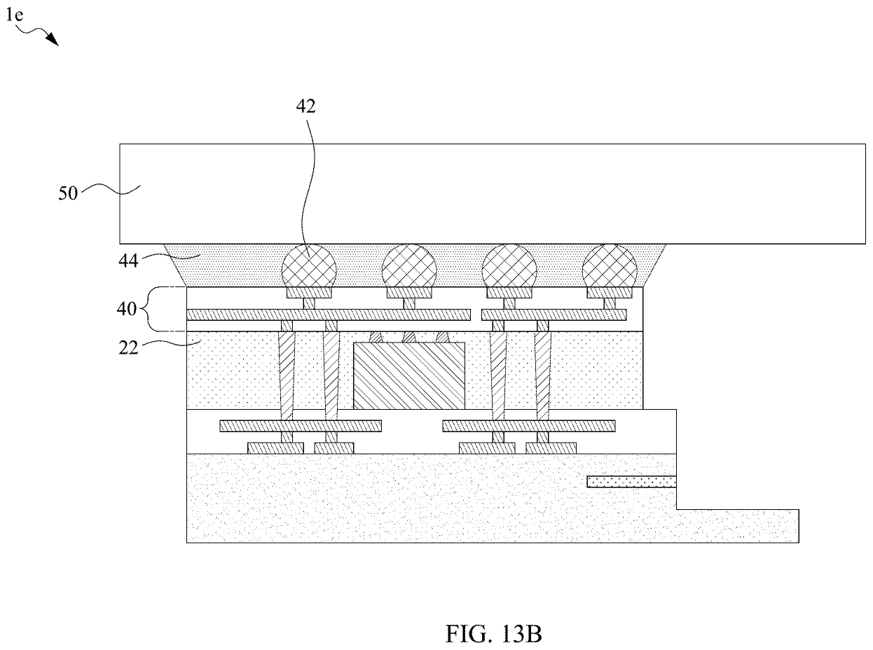

FIG. 13A and FIG. 13B illustrate various stages of an example of a method for manufacturing an optoelectronic package according to some embodiments of the present disclosure. The initial stage of the illustrated process is the same as, or similar to, the stage illustrated in FIG. 12A through FIG. 12E. FIG. 13A depicts a stage subsequent to that depicted in FIG. 12E.

Referring to FIG. 13A, an electronic component 30 may be attached to the upper surface of the redistribution structure 21a. In some embodiments, the electronic component 30 is attached to the upper surface of the redistribution structure 21a by a DAF. In some embodiments, the surface 30s1 of the electronic component 30 is a backside surface, and the surface 30s2 of the electronic component 30 is an active surface. A dummy die 60 may be provided to cover the recess region R3 of the photonic component 10 as illustrated in FIG. 12F.

Referring to FIG. 13B, an encapsulant 22, a redistribution structure 40, electrical connections 42 and an underfill 44 may be formed. The resulting structure may be attached and electrically connected to the circuit structure 50 through the electrical connections 42 as illustrated in FIG. 12K. As a result, an optoelectronic package, such as the optoelectronic package 1e as shown in FIG. 5, may be produced. The stages from FIG. 13A to FIG. 13B may be the same as or similar to those from FIG. 12F to FIG. 12J.

FIG. 14 illustrates a cross-sectional view of a comparative optoelectronic package 2. The optoelectronic package 2 may include a photonic component 10′, electrical connections 16′, an underfill 18′, a redistribution structure 21′, an encapsulant 22′, an electronic component 30′, a redistribution structure 40′, electrical connections 42′, an underfill 44′, and a circuit structure 50′. The manufacturing processes for forming the optoelectronic package 2 may begin with a stage in which the singulated electronic component 30′ is encapsulated by the encapsulant 22′. Next, the redistribution structures 21′ and 40′ are formed on two opposite surfaces of the encapsulant 22′. The photonic component 10′ may be jointed to the redistribution structure 21′ through the electrical connections 16′. The circuit structure 50′ may be jointed to the redistribution structure 40′ through the electrical connection 42′. In this condition, the intermediate structure including the redistribution structure 21′, the encapsulant 22′, the electronic component 30′ and the redistribution structure 40′ may have a relatively large warpage due to the coefficient of thermal expansion (CTE) mismatch among various materials involved therein, which may cause solder skip when jointing the redistribution structure 21′ and the electrical connections 16′. Further, since the electrical connections 16′ are needed to electrically connect the photonic component 10′ and the redistribution structure 21′, the optoelectronic package 2 is relatively thick in comparison with the embodiments of the present disclosure.

Unlike the comparative example of FIG. 14, in the optoelectronic package according to the present disclosure, the redistribution structure may be directly formed on the active surface of the photonic component, and the electrical connections 16′ and underfill 18′ shown in FIG. 14 are no longer necessary. As a result, the overall thickness of the optoelectronic package can be reduced. In addition, since the photonic component is relatively thick, the whole structure of the redistribution structure and the photonic component may have a relatively small warpage compared to the intermediate structure of FIG. 14, which may prevent from subsequent manufacturing problems (such as solder skip).

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to +5%, less than or equal to +4%, less than or equal to +3%, less than or equal to +2%, less than or equal to +1%, less than or equal to ±0.5%, less than or equal to ±0.1%, or less than or equal to ±0.05%. For example, two numerical values can be deemed to be “substantially” the same or equal if a difference between the values is less than or equal to +10% of an average of the values, such as less than or equal to +5%, less than or equal to +4%, less than or equal to +3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. Such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An optoelectronic package, comprising:
a photonic component having an active surface;
a connection structure in contact with the active surface of the photonic component; and
an electronic component embedded in the connection structure, wherein the connection structure comprises a first redistribution structure in contact with the active surface of the photonic component.

2. The optoelectronic package of claim 1, wherein the electronic component is electrically connected to the first redistribution structure.

3. The optoelectronic package of claim 2, wherein the electronic component is electrically connected to the first redistribution structure through a solder element.

4. The optoelectronic package of claim 1, wherein the connection structure comprises a conductive pillar disposed adjacent to a lateral surface of the electronic component.

5. The optoelectronic package of claim 4, wherein the connection structure comprises an encapsulant covering the electronic component and the conductive pillar.

6. The optoelectronic package of claim 5, further comprising:
a solder element electrically connected to the electronic component and covered by the encapsulant.

7. The optoelectronic package of claim 5, wherein the encapsulant covers a lateral surface of the first redistribution structure.

8. The optoelectronic package of claim 5, wherein the conductive pillar is directly disposed on the first redistribution structure.

9. The optoelectronic package of claim 5, wherein a lateral surface of the photonic component and a lateral surface of the encapsulant collectively define a stepped structure.

10. An optoelectronic package, comprising:
a photonic component having a recess region on an active surface of the photonic component and a waveguide exposed from the recess region;
an electronic component disposed over the active surface of the photonic component; and
an encapsulant encapsulating the electronic component, wherein a lateral surface of the encapsulant is noncoplanar with a lateral surface of the recess region of the photonic component.

11. The optoelectronic package of claim 10, further comprising:
a first redistribution structure disposed between the photonic component and the electronic component, wherein a lateral surface of the first redistribution structure is substantially coplanar with the lateral surface of the recess region of the photonic component.

12. The optoelectronic package of claim 11, wherein a lateral surface of the first redistribution structure is substantially coplanar with the lateral surface of the encapsulant.

13. The optoelectronic package of claim 10, further comprising:
a dummy residue covering the lateral surface of the encapsulant.

14. The optoelectronic package of claim 10, further comprising:
a second redistribution structure separated from the first redistribution structure by the encapsulant, wherein the encapsulant has a surface abutting the second redistribution structure, and a portion of the surface of the encapsulant is exposed from the second redistribution structure.

15. The optoelectronic package of claim 10, further comprising:
a collimator element disposed within a recess region of the encapsulant.

16. An optoelectronic package, comprising:
an electronic component having a first surface;
a first redistribution structure disposed over the first surface of the electronic component; and
a photonic component disposed over the first redistribution structure,
wherein a via of the first redistribution structure is tapered toward the photonic component.

17. The optoelectronic package of claim 16, further comprising:
an encapsulant encapsulating the electronic component, wherein a portion of the first redistribution structure is exposed from the encapsulant.

18. The optoelectronic package of claim 17, wherein a lateral surface of the encapsulant is substantially coplanar with a lateral surface of the first redistribution structure.

19. The optoelectronic package of claim 16, further comprising:
an encapsulant encapsulating the electronic component; and
a conductive pillar penetrating the encapsulant, wherein the conductive pillar is tapered toward the photonic component.

20. The optoelectronic package of claim 19, further comprising:
a second redistribution structure disposed over a second surface, opposite to the first surface, of the electronic component, wherein a via of the second redistribution structure is tapered toward the electronic component.
